(19) United States
(12) Patent Application Publication
(10) Pub. No.: US 2016/0035997 A1
(43) Pub. Date: Feb. 4, 2016

(54) DISPLAY APPARATUS AND METHOD OF MANUFACTURING THE SAME

(71) Applicant: Samsung Display Co., Ltd., Yongin-city (KR)

(72) Inventor: Byungchun Oh, Yongin-city (KR)

(21) Appl. No.: 14/695,895

(22) Filed: Apr. 24, 2015

(30) Foreign Application Priority Data
Aug. 1, 2014 (KR) 10-2014-0099244

(51) Int. Cl. H01L 51/52; H01L 27/32; H01L 51/56

(52) U.S. Cl. CPC H01L 51/5246; H01L 51/56; H01L 27/3244; H01L 2227/323

(57) ABSTRACT

A display apparatus and a method for manufacturing the same are disclosed. The display apparatus includes: a display substrate, a display portion disposed on the display substrate, a sealing substrate bonded with the display substrate, a sealing portion disposed between the display substrate and the sealing substrate, the sealing portion surrounding a periphery of the display portion, an inner filling layer disposed between the display portion and the sealing substrate, and a filling dam disposed between the sealing portion and the inner filling layer.

### CROSS REFERENCE TO RELATED APPLICATION

This application claims the benefit of Korean Patent Application No. 10-2014-0099244, filed on Aug. 1, 2014, which is hereby incorporated by reference for all purposes as if fully set forth herein.

### BACKGROUND

1. Field

Exemplary embodiments of the present invention relate to a display apparatus and a method of manufacturing the same.

2. Discussion

Display apparatuses, such as organic light-emitting display apparatuses, may be used for mobile devices, such as, for example, smart phones, tablet personal computers, laptops, digital cameras, camcorders, and personal digital assistants, or for electronic/electrical products, such as ultra-thin televisions.

Display apparatuses are sealed to protect the portions of the apparatus for displaying images. Reduction in dead space, which is an unnecessary area of the display apparatuses, and improvement of the structural strength of the display apparatuses, particularly when the apparatus includes sealed portions, have been studied.

### SUMMARY

Exemplary embodiments include a display apparatus and a method for manufacturing the same.

Additional aspects will be set forth in part in the description which follows and, in part, will be apparent from the description, or may be learned by practice of the presented embodiments.

A display apparatus, according to exemplary embodiments of the present invention, includes: a display substrate; a display portion disposed on the display substrate; a sealing substrate bonded with the display substrate; a sealing portion disposed between the display substrate and the sealing substrate, the sealing portion surrounding a periphery of the display portion; an inner filling layer disposed between the display portion and the sealing substrate; and a filling dam disposed between the sealing portion and the inner filling layer.

A method of manufacturing a display apparatus, according to exemplary embodiments of the present invention, include a method of manufacturing a display apparatus includes: disposing a sealing portion on a sealing substrate; disposing a filling dam separated from the sealing portion on the sealing substrate; disposing an inner filling separated from the filling dam on the sealing substrate; and bonding the sealing substrate with a display substrate, wherein a display portion is disposed on the display substrate.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a cross-sectional view of a display apparatus according to one or more exemplary embodiments.

FIG. 2 is an enlarged cross-sectional view of a portion of a display apparatus according to one or more exemplary embodiments.

FIG. 3 is a flowchart according to one or more exemplary embodiments illustrating a process of forming a sealing portion, a filling dam, and an inner filling layer of FIG. 2.

FIG. 4 is a cross-sectional view according to one or more exemplary embodiments of a state in which a sealing portion and a filling dam are formed on a sealing substrate of FIG. 2.

FIG. 5 is a cross-sectional view according to one or more exemplary embodiments of a state in which an inner filling layer is formed on a sealing substrate of FIG. 4.

FIG. 6 is a cross-sectional view according to one or more exemplary embodiments of a state in which a sealing portion, a filling dam, and an inner packed-bed are formed on a sealing substrate.

FIG. 7 is a cross-sectional view according to one or more exemplary embodiments of a state in which a sealing substrate and a display substrate of FIG. 5 are bonded.

FIG. 8 is a perspective view of part of a screen mask according to one or more exemplary embodiments.

FIG. 9 is a cross-sectional view according to one or more exemplary embodiments of a process of forming a filling dam of FIG. 4.

FIG. 10 is a cross-sectional view according to one or more exemplary embodiments of a process of forming an inner filling layer of FIG. 5.

FIG. 11 is a plan view according to one or more exemplary embodiments of state in which a sealing portion, a filling dam, and an inner filling layer are formed on a sealing substrate.

FIG. 12 is a graph of a result of testing falling weight impact strength according to one or more exemplary embodiments.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

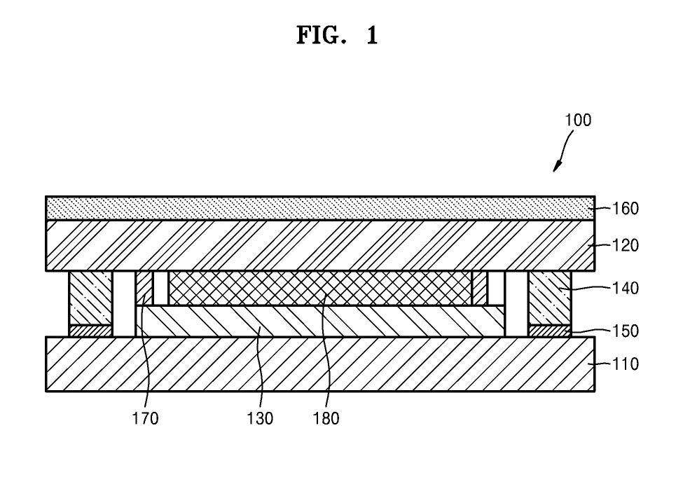

FIG. 1 is a schematic view of display apparatus 100 according to an exemplary embodiment.

According to an exemplary embodiment of the present embodiment, display apparatus 100 may be an organic light-emitting display apparatus (OLED). However, display apparatus 100 is not limited to any one type of display apparatus and may be any display apparatuses that may realize an image by an applied power, such as, for example, a liquid crystal display device (LCD), a field emission display device (FED), or an electronic paper display device (EPD).

Referring to FIG. 1, display apparatus 100 includes display substrate 110 and sealing substrate 120 on display substrate 110.

Display substrate 110 may be a glass substrate having rigidity, a polymer substrate, a film having flexibility, a metal substrate, or a combination thereof. Sealing substrate 120 may be a glass substrate, a resin substrate, a film having flexibility, or a thin layer in which an organic layer and an inorganic layer alternately stacked. Display portion 130 for displaying an image may be on display substrate 110.

Sealing portion 140 may be located between facing surfaces of display substrate 110 and sealing substrate 120. Sealing portion 140 may surround the periphery of display portion 130. Metal pattern layer 150 may also be located between display substrate 110 and sealing portion 140.

Inner filling layer 180 may be located between display substrate 110 and sealing substrate 120. Inner filling layer 180 may fill a space between sealing substrate 120 and display portion 130.

Filling dam 170 may be located between sealing portion 140 and inner filling layer 180.

Function layer 160 of various functions may be located on sealing substrate 120. For example, function layer 160 may include at least one of a polarized plate, a touch screen, and a cover window.

A touch screen, for example, may be an on-cell touch screen panel in which a touch screen pattern is directly located on sealing substrate 120. The polarized plate may prevent or reduce external light from being reflected from display portion 130. The cover window protects display apparatus 100.

In display apparatus 100, dead space corresponding to an outer side of a portion displaying the image may be reduced by various methods. For example, a width of a sealing area in which sealing portion 140 is formed may be reduced. Alternatively, a margin of a cutting area, which is for separating a structure into a plurality of display apparatuses, may be minimized.

However, if the dead space is reduced, a width of sealing portion 140 may also be reduced. Thus, adhesive strength between display substrate 110 and sealing substrate 120 may deteriorate.

According to an exemplary embodiment, inner filling layer 180 may be located between display substrate 110 and sealing substrate 120 to reduce the width of sealing portion 150 and at the same time to increase the strength of display apparatus 100. Inner filling layer 180 may be formed by, for example, a screen printing method, but aspects of the invention are not limited thereto.

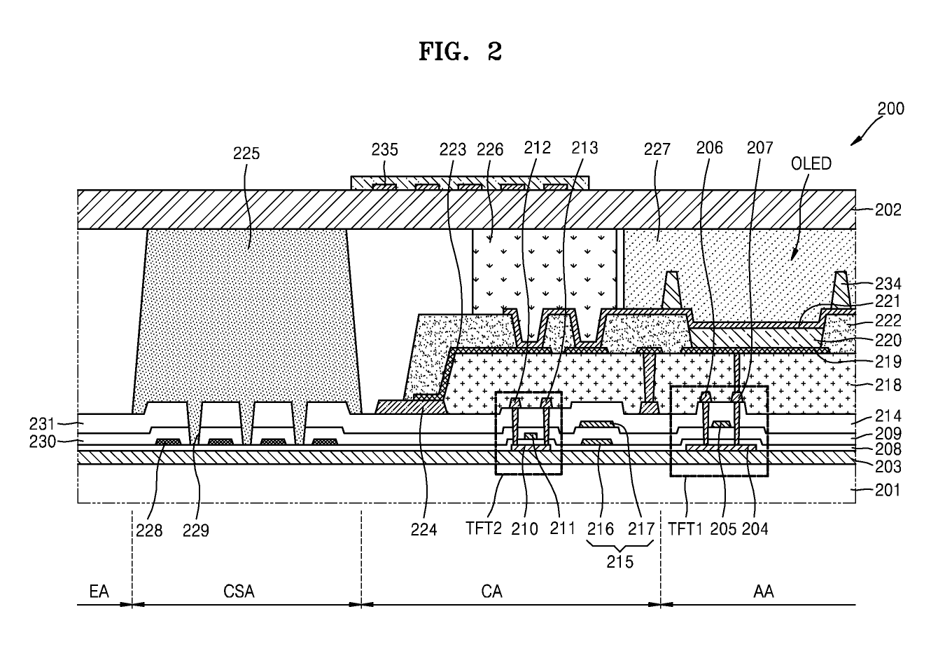

FIG. 2 is an enlarged cross-sectional view of a portion of display apparatus 200 according to an exemplary embodiment.

Referring to FIG. 2, display apparatus 200 includes display substrate 201 and sealing substrate 202 located above display substrate 201.

Display substrate 201 includes active area AA, circuit area CA extending outwards from active area AA, and cell sealing area CSA extending outwards from circuit area CA. Edge area EA including a cutting area may further be located outwards from cell sealing area CSA.

Active area AA may include an area for displaying an image and circuit area CA, which may include an area in which a circuit pattern electrically transmitting signals to a device of active area AA. Cell sealing area CSA may include an area sealing display substrate 201 and sealing substrate 202.

Display substrate 201 may be, for example, a glass substrate, a polymer substrate, a flexible film, a metal substrate, or a combination thereof. Display substrate 201 may be transparent, non-transparent, or half-transparent.

Buffer layer 203 may be located on display substrate 201. Buffer layer 203 may planarize a surface of display substrate 201 and prevent water or external bodies from penetrating into display substrate 201. Buffer layer 203 may be, for example, an inorganic layer such as silicon oxide, an organic layer such as polyimide, or a structure in which the inorganic layer and the organic layer are stacked.

Each of active area AA and circuit area CA may include one or more thin film transistors, such as TFT1 or TFT2. According to an exemplary embodiment, active area AA and circuit area CA may include different types of thin film transistors. However, this is only exemplary, and aspects of the present invention are not limited thereto.

First thin film transistor TFT1 arranged on active area AA includes first semiconductor active layer 204, first gate electrode 205, first source electrode 206, and first drain electrode 207. First gate insulating layer 208 and a second gate insulating layer 209 may be interposed between first gate electrode 205 and first semiconductor active layer 204 to provide insulation between first gate electrode 205 and first semiconductor active layer 204.

Second thin film transistor TFT2 arranged on circuit area CA includes second semiconductor active layer 210, second gate electrode 211, second source electrode 212, and second drain electrode 213. First gate insulating layer 208 may be interposed between second semiconductor active layer 210 and second gate electrode 211 to provide insulation between second semiconductor active layer 210 and second gate electrode 211.

Compared to second thin film transistor TFT2, first thin film transistor TFT1 further includes second gate insulating layer 209 between the semiconductor active layer and the gate electrode. First thin film transistor TFT1 may have a thicker gate insulating layer than second thin film transistor TFT2. When the gate insulating layer is thicker, a driving range of a gate voltage applied to the gate electrode may become wider.

First thin film transistor TFT1 may be a driving thin film transistor driving an organic light-emitting device OLED. A driving range of the driving thin film transistor becoming wider denotes that it may be controlled such that light emitted from the organic light-emitting device OLED may have more gradations.

First gate electrode 205 and second gate electrode 211 may not be located on the same layer. Thus, even if first thin film transistor TFT1 and second thin film transistor TFT2 are arranged proximate to each other, interference may not occur, and thus, a larger number of devices may be arranged in the same area.

First semiconductor active layer 204 and second semiconductor active layer 210 may be located on buffer layer 203. First semiconductor active layer 204 and second semiconductor active layer 210 may be formed by using an inorganic semiconductor, such as, for example, amorphous silicon or poly silicon, or an organic semiconductor.

In exemplary embodiments, first semiconductor active layer 204 and second semiconductor active layer 210 may be formed of an oxide semiconductor. For example, the oxide semiconductor may include oxide of a material selected from metallic elements in groups 4, 12, 13, and 14, such as Zn, In, Ga, Sn, Cd, Ge, or Hf, and a combination thereof.

First gate insulating layer 208 may be located on buffer layer 203, and cover first semiconductor active layer 204 and second semiconductor active layer 210.

Second gate electrode 211 may be located on first gate insulating layer 208 and may overlap a portion of second semiconductor active layer 210.

Second gate insulating layer 209 covers second gate electrode 211.

First gate electrode 205 may be located on second gate insulating layer 209 and may overlap a portion of first semiconductor active layer 204.

First gate electrode 205 and second gate electrode 211 may include a single layer, such as, for example, Au, Ag, Cu, Ni, Pt, Pd, Al, Mo, and Cr, multiple layers, or alloys, such as Al:Nd, and Mo:W.

First gate insulating layer 208 and second gate insulating layer 209 may include an inorganic layer, such as silicon oxide, silicon nitride, and metal oxide. First gate insulating layer 208 and second gate insulating layer 209 may comprise a single layer or multiple layers.

Interlayer insulating layer 214 may be located to cover first gate electrode 205. Interlayer insulating layer 214 may be formed of an inorganic layer, such, for example, as silicon oxide or silicon nitride. In exemplary embodiments, interlayer insulating layer 214 may be formed of an organic layer, such as, for example, polyimide.

First source electrode 206 and first drain electrode 207 are located on interlayer insulating layer 214, and first source electrode 206 and first drain electrode 207 contact first semiconductor active layer 204 through a contact hole. Second source electrode 212 and second drain electrode 213 are formed on interlayer insulating layer 214, and second source electrode 212 and second drain electrode 213 contact second semiconductor active layer 210 through a contact hole.

First source electrode 206, second source electrode 212, first drain electrode 207, and second drain electrode 213 may include, for example, a metal, an alloy, metal nitride, conductive metal oxide, and a transparent conductive material.

The structure of a thin film transistor is not limited to what is described above and may vary. For example, the thin film transistors described above are formed with a top gate structure, however, thin film transistors may also be formed with a bottom gate structure in which first gate electrode 205, for example, is arranged below first semiconductor active layer 204, for example.

Capacitor 215 may be located in circuit area CA. A plurality of capacitors may be located in active area AA.

Capacitor 215 includes a first capacitor electrode 216, a second capacitor electrode 217, and second gate insulating layer 209 interposed between first capacitor electrode 216 and second capacitor electrode 217. First capacitor electrode 216 may be formed of the same material as second gate electrode 211 and second capacitor electrode 217 may be formed of the same material as first gate electrode 205, but aspects of the invention are not limited thereto.

Planarization layer 218 covers first and second thin film transistors TFT1 and TFT2 and capacitor 215. Planarization layer 218 may be located on interlayer insulating layer 214. Planarization layer 218 may remove height differences in interlayer insulating layer 214 caused by underlying different thin film transistor structures, for example, and serves to provide a planarized upper surface to increase the emission efficiency of organic light-emitting device OLED which is to be located on the thin layer. In exemplary embodiments, planarization layer 218 may have a penetration hole exposing a portion of first drain electrode 207.

Planarization layer 218 may be formed as an insulator. For example, planarization layer 218 may be formed as a single-layered or multiple-layered structure by using an inorganic material, an organic material, or an organic/inorganic compound material. Planarization layer 218 may be formed by various deposition methods.

Planarization layer 218 may be formed of an organic material, such as a polyacrylates resin, an epoxy resin, and benzocyclobutene (BCB), or an inorganic material, such as silicon nitride (SiNx).

One of planarization layer 218 and interlayer insulating layer 214 may be omitted.

Organic light-emitting device OLED may be located on planarization layer 218. Organic light-emitting device OLED includes first electrode 219, an intermediate layer including organic emission layer 220, and second electrode 221.

Pixel-defining layer 222 covers planarization layer 218 and a portion of first electrode 219, and defines a pixel area PA (not shown) and a non-pixel area NPA (not shown).

Pixel-defining layer 222 is formed of an organic material or an inorganic material. For example, pixel-defining layer 222 may be formed of an organic material, such as polyimide, polyamide, BCB, a polyacrylates resin, and a phenol resin, or an inorganic material, such as SiNx. Pixel-defining layer 222 may be formed as a single layer or multiple layers.

Intermediate layer 220 may include the organic emission layer (not shown). According to an exemplary embodiment, intermediate layer 220 may include the organic emission layer and further include at least one of a hole injection layer (HIL), a hole transport layer (HTL), an electron transport layer (ETL), and an electron injection layer (EIL). Aspects are not limited thereto. Intermediate layer 220 may include the organic emission layer and further include various function layers.

Light may be emitted due to the combination of holes and electrons, injected from first electrode 219 and second electrode 221 into the organic emission layer of intermediate layer 220.

Second electrode 221 may be located on intermediate layer 220. Second electrode 221 forms an electric field with first electrode 219 so that light may be emitted from intermediate layer 220. First electrode 219 may be patterned for each pixel and second electrode 221 may be formed such that a common voltage is applied to every pixel.

First electrode 219 and second electrode 221 may include a transparent electrode or a reflection electrode.

First electrode 219 functions as an anode and may be formed of various conductive materials. First electrode 219 may be formed as a transparent electrode or a reflection electrode.

For example, when first electrode 219 includes the transparent electrode, first electrode 219 includes a transparent conductive layer, such as ITO, IZO, ZnO, and In₂O₃. When first electrode 219 includes the reflection electrode, first electrode 219 may be formed by forming a reflective layer by using Ag, Mg, Al, Pt, Pd, Au, Ni, Nd, Ir, Cr, or a combination thereof and further forming on the reflective layer a transparent conductive layer, such as ITO, IZO, ZnO, or In₂O₃.

Second electrode 221 may act as a cathode. Second electrode 221 may be formed of the transparent electrode or the reflection electrode.

For example, when second electrode 221 is formed of a transparent electrode, second electrode 221 may be formed by depositing on intermediate layer 220 a metal having a low work function, such as Li, Ca, LiF/Ca, LiF/Al, Al, Mg, or a compound thereof, and further forming on the metal or the compound thereof a transparent conductive layer, such as ITO, IZO, ZnO, or In₂O₃. When second electrode 221 is formed of a reflection electrode, second electrode 221 may be formed of Li, Ca, LiF/Ca, LiF/Al, Al, Mg, or a compound thereof.

First electrode 219 may act as the anode and second electrode 221 may function as the cathode, however, aspects are not limited thereto. For example, first electrode 219 may act as the cathode and second electrode 221 may function as the anode.

Each organic light-emitting device OLED may include one pixel and each pixel may realize a red, green, blue, or white light color. However, aspects are not limited thereto. Intermediate layer 220 may be commonly formed throughout first electrode 219 regardless of locations of pixels. The organic emission layer may be formed such that layers including emission materials emitting red, green, and blue light colors are vertically stacked or the emission materials emitting red, green, and blue light colors are mixed. If the organic emission layer may emit the white light color, other color combinations are also possible. A color conversion layer converting the white light emitted into a predetermined color light or a color filter to convert the white light may be included.

A passivation layer (not shown) may be arranged on second electrode 221. The passivation layer covers the organic light-emitting device OLED. The passivation layer may be formed of an inorganic insulating layer and/or an organic insulating layer.

Spacer 234 may be arranged in the non-pixel area NPA. Spacer 234 is arranged between display substrate 210 and sealing substrate 202. Spacer 234 may be formed to reduce or prevent deterioration of display characteristics due to externals shocks.

Sealing substrate 202 is located above display substrate 201. Sealing substrate 202 may protect the organic light-emitting device OLED and other thin layers from contact with external water or oxygen, for example.

Sealing substrate 202 may be, for example, a glass substrate having rigidity, a polymer substrate, or a film having flexibility. Sealing substrate 202 may have a structure in which an organic layer and an inorganic layer are alternately stacked.

A plurality of touch electrodes 235 may be located on sealing substrate 202 to act as a touch screen. In addition, other layers, such as a polarized film, a color filter, and a cover window, may further be located on sealing substrate 202.

Various circuit patterns may be formed in circuit area CA. For example, a power supply pattern, an antistatic pattern, and other various circuit patterns may be formed.

Circuit wiring 223 is formed in circuit area CA. The circuit wiring 223 may be located on planarization layer 218. The circuit wiring 223 may be formed of the same material as first electrode 219. The circuit wiring 223 may be a wiring that is electrically connected with a device of active area AA, for example, second electrode 221.

Circuit wiring 223 is connected with power wiring 224. Power wiring 224 may be located on interlayer insulating layer 214. Power wiring 224 may be formed of the same material as first source electrode 206, second source electrode 212, first drain electrode 207, and second drain electrode 213. Power wiring 224 may be a wiring to which external power is applied. In exemplary embodiments, power wiring 224 may have a triple-layered structure of Ti/Al/Ti.

Circuit wiring 223 and power wiring 224 may be arranged on different layers.

For example, circuit wiring 223 may be located on planarization layer 218. Circuit wiring 223 may be formed by the same process using the same material as first electrode 223. The power wiring 224 may be located on interlayer insulating layer 214. The power wiring 224 may be formed by the same process using the same material as first source electrode 206, second source electrode 212, first drain electrode 207, and second drain electrode 213.

An end of circuit wiring 223 may contact power wiring 224. In exemplary embodiments, circuit wiring 223 may partially or entirely overlap power wiring 224.

Sealing portion 225 is formed in cell sealing area CSA. Sealing portion 225 is located between display substrate 201 and sealing substrate 202. Sealing portion 225 may be arranged along a circumference of circuit area CA.

Sealing portion 225 may include a glass frit. The glass frit includes glass powder and oxide powder. An organic material may be added to the glass frit including the oxide powder to produce a paste in a gel state to be fired at a temperature of about 300° C. to about 500° C. When the glass frit is fired, the organic material may dissipate into the air and the paste in the gel state may be hardened to remain as the frit in a solid state.

Metal pattern layer 228 may be located below sealing portion 225. Metal pattern layer 228 may absorb heat of a laser or reflect the laser to transmit the heat to sealing portion 225.

Metal pattern layer 228 may be located on the same layer by using the same material as second gate electrode 211 of second thin film transistor TFT2. In exemplary embodiments, metal pattern layer 228 may be located on the same layer by using the same material as first gate electrode 205 of first thin film transistor TFT1.

Metal pattern layer 228 may be a single layer or multiple layers including, for example, Au, Ag, Cu, Ni, Pt, Pd, Al, Mo, and Cr. The metal pattern layer 228 may be alloys, such as, for example, Al:Nd and Mo:W.

At least one insulating layer, for example, first insulating layer 230 or second insulating layer 231 is located on metal pattern layer 228. When first insulating layer 230 or second insulating layer 231 is arranged on metal pattern layer 228, a hillock phenomenon or bubble generation in the metal pattern layer 228 due to a radical temperature rise caused by heat from the laser may be prevented or reduced.

First insulating layer 230 and second insulating layer 231 may include a plurality of openings 229. Plurality of openings 229 may enlarge a contact area of a first sealing portion 225 and first and second insulating layers 230 and 231. Accordingly, the adhesive strength of first sealing portion 225 and first and second insulating layers 230 and 231 may be increased.

First insulating layer 230 may be located on the same layer by using the same material as second gate insulating layer 209. Second insulating layer 231 may be located on the same layer by using the same material as interlayer insulating layer 214.

Inner filling layer 227 may be formed on active area AA.

Space, or an air layer, may exist between a display portion DP (not shown) and sealing substrate 202 in active area AA. The inner filling layer 227 may fill at least a portion of the space between display portion DP and sealing substrate 202. According to exemplary embodiment, inner filling layer 227 may completely fill the space between the display portion DP and sealing substrate 202.

Inner filling layer 227 may be formed by using a liquid filling material having a high transmittance rate. Inner filling layer 227 may include an inorganic material, for example, a silicon-based material. Since inner filling layer 227 may fill the space between the display portion DP and sealing substrate 202, the shock strength of display substrate 201 and sealing substrate 202 bonded with each other may be increased.

Meanwhile, since inner filling layer 227 is formed by using a liquid filling material, the liquid filling material may spread to undesired areas during a manufacturing process. To prevent or reduce this, filling dam 226 may be formed between inner filling layer 227 and sealing portion 225. Filling dam 226 may block the raw material of inner filling layer 226 from spreading to other areas.

In exemplary embodiments, filling dam 226 may be formed in circuit area CA. Filling dam 226 may be arranged along a circumference of inner filling layer 227. Filling dam 226 may be separated from inner filling layer 227. In exemplary embodiments, filling dam 226 and inner filling layer 227 may contact each other during a bonding process of display substrate 201 and sealing substrate 202.

Filling dam 226 may include an inorganic material, for example, a silicon-based material. In exemplary embodiments, filling dam 226 may be formed of the same material as inner filling layer 227.

Sealing portion 225, filling dam 226, and inner filling layer 227 may be formed on sealing substrate 202 by a screen printing method using the raw material of each of sealing portion 225, filling dam 226, and inner filling layer 227.

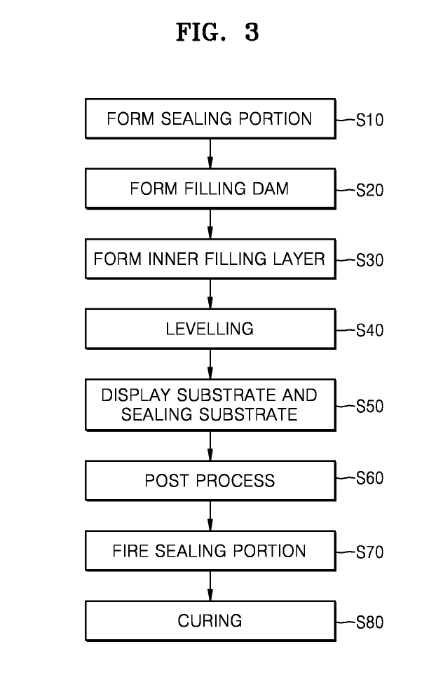

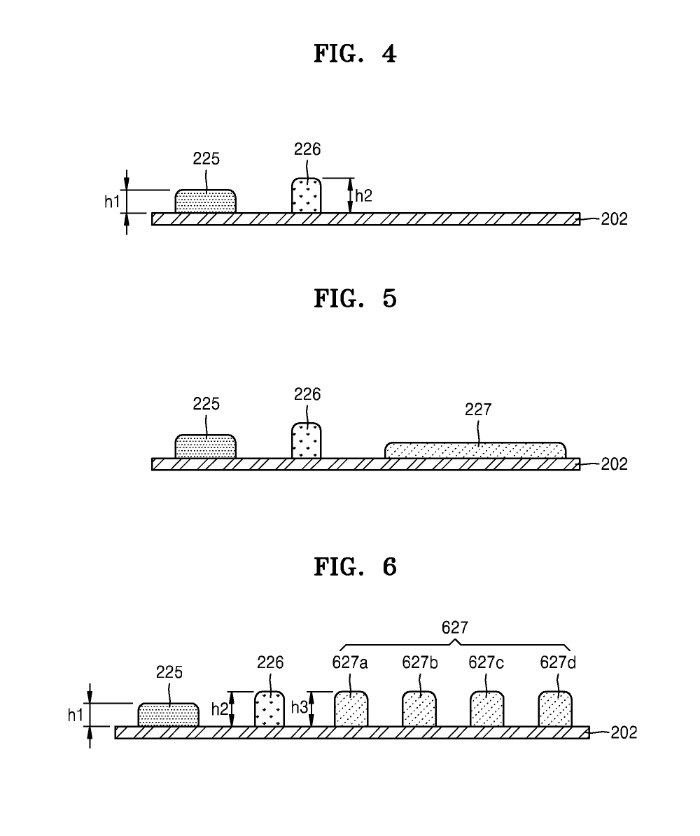

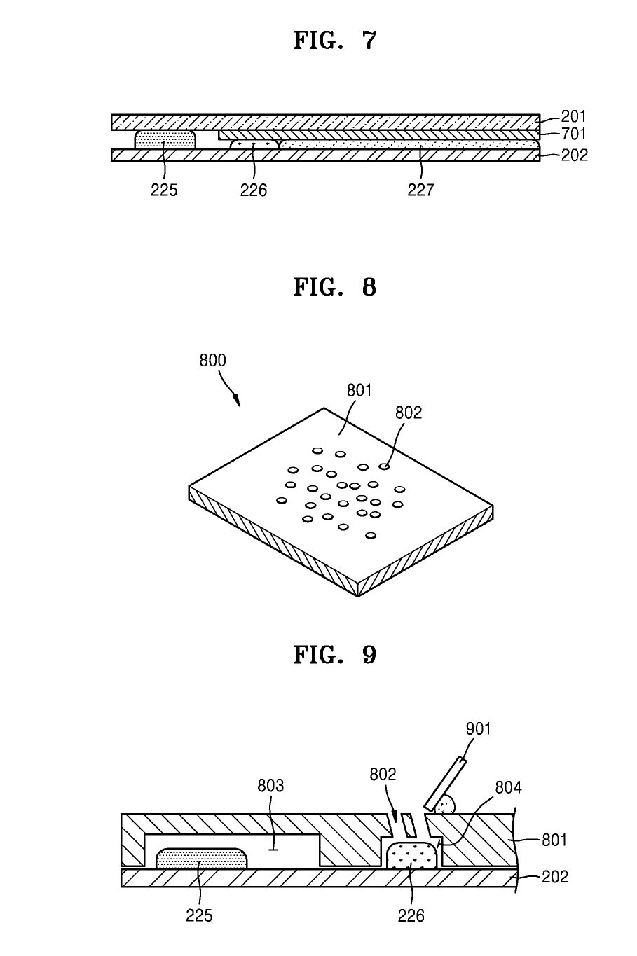

FIG. 3 is a flowchart sequentially illustrating a process of forming sealing portion 225, filling dam 226, and inner filling layer 227. FIG. 4 is a cross-sectional view illustrating a state in which sealing portion 225 and filling dam 226 are located on sealing substrate 202. FIG. 5 is a cross-sectional view illustrating a state in which inner filling layer 227 is located on sealing substrate 202 of FIG. 4. FIG. 7 is a cross-sectional view illustrating a state in which sealing substrate 202 and display substrate 201 of FIG. 5 are bonded with each other.

Referring to FIG. 4, sealing portion 225 is located on sealing substrate 202 in operation S10. The sealing portion 225 may be formed along an edge of sealing substrate 202. The sealing portion 225 may be formed in the sealing area (CSA of FIG. 2). In exemplary embodiments, sealing portion 225 may be formed by using a screen mask having a pattern hole with a shape corresponding to sealing portion 225. After sealing portion 225 is printed, drying and firing processes are performed. The firing may be performed at a temperature around about 400° C.

After the first screen printing is performed, filling dam 226 is located on sealing substrate 202 in operation S20. The filling dam 226 may be formed at a location proximate to sealing portion 225. The filling dam 226 may be formed in circuit area (CA of FIG. 2).

In exemplary embodiments, filling dam 226 may be formed by using a screen mask for the filling dam, the mask having a pattern hole with a shape corresponding to filling dam 226. Referring to FIG. 8, the screen mask for filling dam 800 includes screen mask body 801. Screen mask body 801 may be a metal plate, the thickness being the same as or smaller than 100 micrometers. Pattern hole 802 to form filling dam 226 is formed on mask body 801. Pattern hole 802 may be formed by, for example, a photo, etching, or laser process.

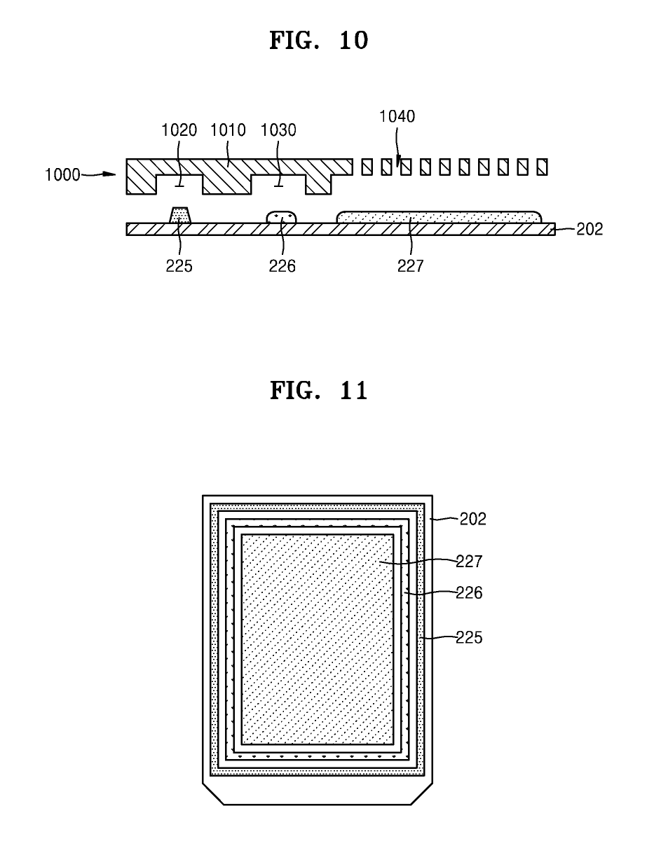

As depicted in FIG. 9, first accommodation portion 803 accommodating sealing portion 225 may be formed in screen mask body 801. Sealing portion 225 is located on sealing substrate 202 by the first screen printing. To form filling dam 226, screen mask body 801 may be located on sealing substrate 202. Because sealing portion 225 is already being located on sealing substrate 202, interference may occur between sealing portion 225 and the screen mask body 801 for filling dam 226.

To prevent or reduce interference, first accommodation portion 803 which is a space capable of accommodating sealing portion 225 may be formed on the surface of screen mask body 801 for filling dam 226 that faces sealing substrate 202. First accommodation potion 803 may be formed by making a thickness of screen mask body 801 smaller than other portions by a half-etching method. Accordingly, when screen printing filling dam 226, interference between sealing portion 225 and screen mask body 801 may not occur.

Second accommodation portion 804 accommodating filling dam 226 is formed between screen mask body 801 and a portion in which filling dam 226 is located. Second accommodation portion 804 may be also formed by making the thickness of screen mask body 801 smaller than other portions by a half-etching method.

When the raw material of filling dam 226 is printed on sealing substrate 202 by placing a squeeze 901 on screen mask body 801 and moving squeeze 901 in a direction, the raw material is filled into second accommodation potion 804 through pattern hole 802. Here, the raw material of filling dam 226 may include a liquid crystal inorganic material, for example, a silicon-based material. Thus, filling dam 226 of a desired shape may be formed on sealing substrate 202.

After filling dam 226 is formed, filling dam 226 may be half-hardened. Filling dam 226 may not be completely hardened to allow for improved adhesion of display substrate 201 and sealing substrate 202 when display substrate 201 and sealing substrate 202 are bonded with each other. Height h2 of filling dam 226 may be greater than height h1 of sealing portion 225, however, due to contraction during the hardening process, height h1 of sealing portion 225 may be greater than height h2 of the filling dam 226.

Referring to FIG. 5, after the second screen printing is performed, inner filling layer 227 is formed on sealing substrate 202 in operation S30. Inner filling layer 227 may be formed in the active area (AA of FIG. 2) in which display portion DP is formed.

Inner filling layer 227 may be sequentially formed on sealing substrate 202. The inner filling layer 227 may be spread throughout an area corresponding to sealing substrate 202, to fill a space between display portion DP and sealing substrate 202. The inner filling layer 227 may be completely filled on sealing substrate 202, but aspects of the invention are not limited thereto.

In exemplary embodiments, inner filling layer 227 may be partially filled as illustrated in FIG. 6 Inner filling layer 627 having a plurality of inner filling portions 627a, 627b, 627c, and 627d, having a dot shape, may be located on sealing substrate 202. The plurality of inner filling portions 627a, 627b, 627c, and 627d may be arranged separate from each other.

In exemplary embodiments, plurality of inner filling portions 627a, 627b, 627c, and 627d may be integrally combined by being spread to the periphery when display substrate 201 and sealing substrate 202 are bonded with each other. In exemplary embodiments, when a height h3 of plurality of inner filling portions 627a, 627b, 627c, and 627d is taller than h1, the height of sealing portion 225, and h2, the height of filling dam 226, the plurality of inner filling potions 627a, 627b, 627c, and 627d may be partially filled.

Inner filling layer 227 may be formed by using a screen mask for an inner filling layer having a pattern hole for forming inner filling layer 227. Referring to FIG. 10, screen mask 1000 for the inner filling layer includes a screen mask body 1010. Screen mask body 101 may be a metal plate with a thickness being the same as or smaller than 100 micrometers. Pattern hole 1040 for forming inner filling layer 227 may be formed on screen mask body 1010.

First accommodation potion 1020 accommodating sealing portion 225 and second accommodation portion 1030 accommodating filling dam 226 may be formed in screen mask body 1010.

Sealing portion 225 may be formed on sealing substrate 202 by the first screen printing and filling dam 226 may be formed on sealing substrate 202 by the second screen printing.

To form inner filling layer 227, screen mask body 1010 may be placed on sealing substrate 202. Because sealing portion 225 and filling dam 226 are already located on sealing substrate 202, interference may occur between sealing portion 225 and the filling dam 226, and screen mask body 1010 for inner filling layer 227.

To prevent or reduce interference, first accommodation portion 1020 which is a space capable of accommodating sealing portion 225 and second accommodation portion 1030 which is a space for accommodating filling dam 226 may be formed in screen body 1010 for the inner filling layer facing sealing substrate 202. First accommodation portion 1020 and second accommodation portion 1030 may be formed by making the thickness of screen mask body 1010 smaller than other portions by a half-etching method. Accordingly, when screen printing inner filling layer 227, interference may not occur between sealing portion 225 and filling dam 226, and screen mask body 1010.

Screen mask body 1010 is placed on sealing substrate 202 and the raw material for the inner filling layer may pass through pattern hole 1040 to be printed on sealing substrate 202. The raw material for the inner filling layer may include a liquid crystal inorganic material, for example, a silicon-based material.

Filling dam 226 may be formed around the circumference of inner filling layer 227. When the liquid raw material for the inner filling layer is printed on sealing substrate 202, filling dam 226 may block the liquid raw material for the inner filling layer from spreading to other portions.

As shown in operation S40, leveling of inner filling layer 227 may be performed. A surface of inner filling layer 227 may be planarized through the leveling process.

Next, as illustrated in FIG. 7, sealing substrate 202 and display substrate 201 may be bonded with each other in operation S50.

Sealing substrate 202 on which sealing portion 225, filling dam 226, and inner filling layer 227 are formed, and display substrate 201 on which the plurality of thin film transistors, the organic light-emitting device (OLED), and pattern layer 701 including various circuit pattern layers are formed, are bonded in a vacuum.

When sealing substrate 202 and display substrate 201 are bonded, the filling dam (in a half-hardened state) and inner filling layer 227 may be spread to the space between sealing substrate 202 and display substrate 201 to fill the inside of display apparatus 200. In exemplary embodiments, filling dam 226 and inner filling layer 227 may contact each other.

After the bonding is completed, a post processing may be performed in operation S60. To ensure the filling stability of filling dam 226 and inner filling layer 227 inside display apparatus 200, a predetermined time may need to pass.

Next, sealing portion 225 is fired as shown in operation S70. Sealing portion 225 may go through an additional firing process using, for example, a laser.

Next, a curing process is performed as shown in operation S80. The curing process corresponds to a later final hardening process.

FIG. 11 is a plan view of state in which sealing portion 225, filling dam 226, and inner filling layer 227 are formed on a sealing substrate, having the structure as described above.

Sealing portion 225 is located on sealing substrate 202 along an edge, and is formed in an sealing area (CSA of FIG. 2).

Inner filling layer 227 is located in an active area (AA of FIG. 2) in which display portion DP is formed. Inner filling layer 227 may be formed throughout active area AA.

Filling dam 226 is located between sealing portion 225 and inner filling layer 227. Filling dam 226 is formed in a circuit area (CA of FIG. 2).

As shown above, sealing portion 225, filling dam 226, and inner filling layer 227 may be sequentially located on sealing substrate 202 by the first through third screen printings.

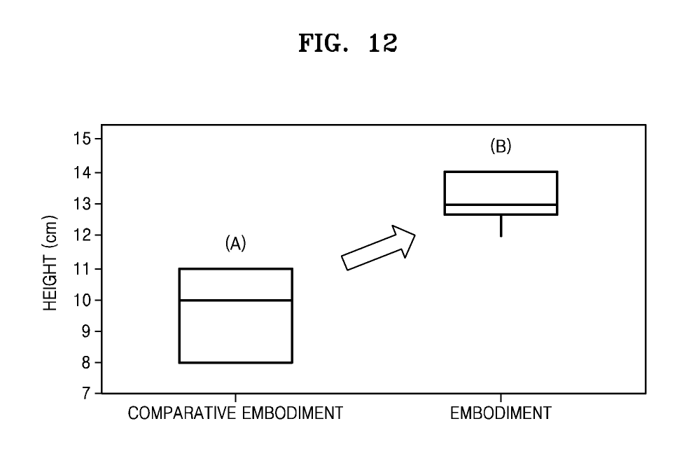

FIG. 12 is a graph illustrating a test results for a falling dart impact strength test according to a conventional embodiment A and an exemplary embodiment B.

In conventional embodiment A, only a sealing portion is formed, whereas in an exemplary embodiment B, sealing portion 225, filling dam 226, and inner filling layer 227 of FIG. 2 are formed. The test of the falling dart impact strength may be conducted to check for damage to a display panel caused by dropping an object weighing around 200 grams, for example, a urethane ball, on the panel at different heights.

Referring to FIG. 12, the exemplary embodiment's strength is increased 40% compared to the conventional embodiment. Formation of the inner filling layer inside the display apparatus may increase the strength.

As described above, according to exemplary embodiments, the adhesive strength of a display substrate and a sealing substrate may be increased.

It should be understood that the exemplary embodiments described herein should be considered in a descriptive sense only and not for purposes of limitation. Descriptions of features or aspects within each embodiment should typically be considered as available for other similar features or aspects in other embodiments.

While one or more embodiments of the present invention have been described with reference to the figures, it will be understood by those of ordinary skill in the art that various changes in form and details may be made herein without departing from the spirit and scope of the present invention as defined by the following claims.

What is claimed is:

1. A display apparatus comprising:
a display substrate;
a display portion disposed on the display substrate;
a sealing substrate bonded with the display substrate;
a sealing portion disposed between the display substrate and the sealing substrate, the sealing portion surrounding a periphery of the display portion;
an inner filling layer disposed between the display portion and the sealing substrate; and
a filling dam disposed between the sealing portion and the inner filling layer.

2. The apparatus of claim 1, wherein the inner filling layer occupies at least a portion of space between the display portion and the sealing substrate.

3. The apparatus of claim 1, wherein the inner filling layer substantially completely occupies space between the display portion and the sealing substrate.

4. The apparatus of claim 1, wherein the inner filling layer comprises an inorganic material.

5. The apparatus of claim 1, wherein the filling dam is disposed along a circumference of the inner filling layer.

6. The apparatus of claim 5, wherein the filling dam is separated from the inner filling layer.

7. The apparatus of claim 1, wherein the filling dam comprises an inorganic material.

8. The apparatus of claim 7, wherein the filling dam comprises the same material as the inner filling layer.

9. The apparatus of claim 1, wherein the sealing portion comprises a glass frit.

10. The apparatus of claim 1, wherein:
the display substrate comprises an active area in which the display portion is disposed, a circuit area extending outwards from the active area, and a sealing area extending outwards from the circuit area;
the inner filling layer is disposed on the active area;
the filling dam is disposed on the circuit area; and
the sealing portion is disposed on the sealing area.

11. The display apparatus of claim 10, wherein circuit wiring, to electrically connect with a device in the active area, and power wiring, to electrically connect with the circuit wiring and to supply power from an external source, are formed in the circuit area.

12. The display apparatus of claim 1, wherein the display portion comprises:
a thin film transistor, a gate electrode, a source electrode, and a drain electrode, the thin film transistor comprising a semiconductor active layer; and
an organic light-emitting device electrically connected with the thin film transistor, the organic light-emitting device comprising a first electrode, an intermediate layer comprising an organic emission layer, and a second electrode.

13. A method of manufacturing a display apparatus, the method comprising:
disposing a sealing portion on a sealing substrate;
disposing a filling dam separated from the sealing portion on the sealing substrate;
disposing an inner filling separated from the filling dam on the sealing substrate; and
bonding the sealing substrate with a display substrate, wherein a display portion is disposed on the display substrate.

14. The method of claim 13, wherein each of the sealing portion, the filling dam, and the inner filling layer are formed by a screen printing method.

15. The method of claim 14, wherein the sealing portion is formed by using a screen mask for a sealing portion, then the filling dam is formed by using a screen mask for a filling dam, and then the inner filling layer is formed using a screen mask for an inner filling layer, each of the masks having a pattern hole.

16. The method of claim 15, wherein an accommodation portion accommodating the sealing portion is formed on a surface of the screen mask for the filling dam facing the sealing substrate when the filling dam is being formed on the sealing substrate, the accommodation portion accommodating the sealing portion during formation of the filling dam.

17. The method of claim 15, wherein a first accommodation portion accommodating the sealing portion and a second accommodation portion accommodating the filling dam are formed on a surface of the screen mask for the inner filling layer facing the sealing substrate when the inner filling layer is being formed, the first accommodation portion and the second accommodation portion respectively accommodating the sealing portion and the filling dam during formation of the inner filling layer.

18. The method of claim 13, wherein a space between the display portion and the sealing substrate is substantially occupied with the inner filling layer.

19. The method of claim 13, wherein the filling dam is disposed along a circumference of the inner filling layer.

20. The method of claim 13, wherein when the sealing substrate and the display substrate are bonded, the filling dam and the inner filling layer occupy space between the sealing substrate and the display substrate.
